(19) United States
(12) Patent Application Publication
(10) Pub. No.: US 2015/0333141 A1
(43) Pub. Date: Nov. 19, 2015

(54) A HIGH ELECTRON MOBILITY DEVICE BASED ON THE GATE-FIRST PROCESS AND THE PRODUCTION METHOD THEREOF

(71) Applicant: FUDAN UNIVERSITY, Shanghai (CN)

(72) Inventors: Xiaoyong Liu, Shanghai (CN); Pengfei Wang, Shanghai (CN); Wei Zhang, Shanghai (CN); Qingqing Sun, Shanghai (CN); Peng Zhou, Shanghai (CN)

(21) Appl. No.: 14/651,984

(22) PCT Filed: Mar. 24, 2014
(86) PCT No.: PCT/CN2014/073943

§ 371 Date: Jun. 12, 2015

(30) Foreign Application Priority Data
Mar. 25, 2013 (CN) 201310098165.2
Mar. 25, 2013 (CN) 201310098546.0
Mar. 25, 2013 (CN) 201310098550.7

(51) Int. Cl. H01L 29/423; H01L 29/40; H01L 29/778; H01L 29/207; H01L 21/265; H01L 21/3065; H01L 21/308; H01L 21/311; H01L 21/3213; H01L 29/20; H01L 29/66

(52) U.S. Cl. CPC H01L 29/42364; H01L 29/2003; H01L 29/402; H01L 29/7786; H01L 29/207; H01L 29/66462; H01L 21/3065; H01L 21/3085; H01L 21/31116; H01L 21/31144; H01L 21/32133; H01L 21/32139; H01L 29/401; H01L 21/26546

(57) ABSTRACT

The present disclosure belongs to the technical field of radio frequency power devices, and more specifically, to a high electron mobility device based on the gate-first process and the production method thereof. The high electro mobility device is made by adopting the gate-first process according to the present disclosure, wherein gate dielectric sidewalls are utilized to implement the self-alignment of the gate and source; besides, the source and drain of the device can be formed directly by use of the alloying process, the iron implanting process or epitaxy process after formation of the gate since the gate is protected by the passivating layer, featuring a simple technological process while reducing parameter shift of products and enhancing the electrical properties of high electron mobility devices.

### BACKGROUND OF THE DISCLOSURE

1. Technical Field

The present disclosure relates to a radio frequency power device, and more specifically, to a high electron mobility device based on the gate-first process and the production method thereof, belonging to the field of radio frequency power devices.

2. Description of Related Art

High electron mobility transistors (HEMT) are widely regarded as one of the most promising high-speed electronic devices. With their advantageous features, such as ultra high-speed, low power consumption and low noise level (especially at low temperature), the HEMT device satisfies the special needs of ultra high-speed computers, signal processing, satellite communications, etc. in purpose and hence receive much attention. As a new generation of microwave and millimeter-wave devices, the HEMT has unraveled advantages in frequency, gain and efficiency. After more than a decade of development, the HEMT device possesses the properties of excellent microwave and millimeter-wave and becomes a main device for low-noise microwave and millimeter-wave amplifiers in fields like 2˜100 GHz satellite communications and radio astronomy. Moreover, the HEMT device is also used for making the core parts of microwave mixers, oscillators and broadband traveling-wave amplifiers.

The GaN-based HEMT radio frequency power devices in prior art are mostly produced by using the gate-last process. The process flow of the production mainly includes: first, make a source and a drain; photo-etch ohmic contact holes, form a multi-layer electrode structure by electron-beam evaporation, form source-drain contact by use of the lift-off process, and form good source-drain ohmic contact at 900° C. in 30 sec by using a piece of rapid thermal annealing (RTA) equipment under the protection of argon gas; next, photo-etch the regions that need to be etched away, and etch steps by using a piece of reactive ion beam etching (RIE) equipment and introducing boron chloride; finally, form a Schottky barrier gate metal by using photo-etching, electro-beam evaporation and lift-off processes again. However, as the devices become smaller and smaller, it is difficult to implement accurate location alignment between the gate and the source, drain of the HEMT device by means of the gate-last process, resulting in parameter drift of products.

### SUMMARY OF THE DISCLOSURE

The object of the present disclosure is to provide a high electron mobility device based on the gate-first process and the production method thereof so as to implement self-alignment of the gate and the source of high electron mobility devices, reduce parameter drift of products and enhance the electrical properties of high electron mobility devices.

The present disclosure provides a high electron mobility device based on the gate-first process, comprising:

a GaN buffer layer, a GaN channel layer and an isolating layer formed in turn on the substrate;

a gate dielectric layer formed on the AlGaN isolating layer;

wherein, also comprising:

a gate formed on the gate dielectric layer and a passivating layer on the gate;

a gate dielectric sidewall formed on either side of the gate;

a drain and a source formed respectively on the sides of the gate dielectric layer;

a dielectric layer formed between the gate dielectric sidewall close to the drain and the drain to allow the dielectric sidewall close to the drain to extend and make the dielectric sidewalls on the sides of the gate asymmetric in shape;

a field plate covered on the gate dielectric sidewall close to the drain, wherein the field plate is connected with the source and extends over the dielectric layer and the passivating layer on the gate along the length of the current channel of the device.

Furthermore, the isolating layer is AlGaN or indium nitride.

Furthermore, the source and the drain are located on the isolating layer and formed by alloy materials.

Furthermore, the source and the drain are located in the isolating layer and formed by the silicon iron doped region in the isolating layer.

Furthermore, the source and the drain are located on the AlGaN channel layer and formed by silicon doped GaN or AlGaN materials.

The present disclosure provides a method for producing the high electron mobility device based on the gate-first process above, comprising:

deposit an AlGaN buffer layer, a GaN channel layer and an isolating layer in turn on the substrate;

etch the isolating layer, the GaN channel layer and the AlGaN buffer layer in turn to form an active region with a photo-resist as the etching stop layer, followed by removal of the resist;

deposit the first layer of insulating film, the first layer of conductive film and the second layer of insulating film in turn on the exposed surface of the structure formed;

define the location of the gate of the device by photo-etching and development;

etch away the second layer of insulating film and the first layer of conductive film exposed in turn with a photo-resist as the etch stop layer, followed by removal of the resist, in this way the remaining first layer of conductive film and second layer of insulating film form the gate and the passivating layer on the gate;

deposit the third layer of insulating film on the exposed surface of the structure formed, define the locations of the source and the drain of the device by masking, exposure and development, etch away the exposed third layer of insulating film with a photo-resist as the etching stop layer, and continue to etch away the first layer of insulating film exposed to expose the isolating layer, followed by removal of the resist, in this way the remaining third layer of insulating film forms the gate dielectric sidewalls on the sides of the gate and the dielectric layer between the gate dielectric sidewall close to the drain and the drain;

form the source and drain of the device;

form a field plate covering the gate dielectric sidewall close to the drain, wherein the field plate is connected with the source and extends over the dielectric layer and the passivating layer on the gate formed along the length of the current channel of the device.

Furthermore, the isolating layer is AlGaN or indium nitride.

Furthermore, the formation of the source and the drain of the device includes implanting silicon ions into the AlGaN isolating layer exposed to form the source and the drain of the device in the AlGaN isolating layer.

Furthermore, the formation of the source and the drain of the device includes forming the source and the drain on the AlGaN isolating layer exposed by the lift-off process and the alloying process.

Furthermore, the formation of the source and the drain of the device includes: continue to etch away the AlGaN isolating layer exposed to expose the GaN channel layer formed; grow silicon-doped GaN or AlGaN by use of the epitaxy process, form the source and the drain of the device on the GaN channel layer exposed.

Furthermore, the first layer of the insulating film is any one of silicon oxide, silicon nitride, hafnium oxide or Al₂O₃, while the second layer of insulating film and the third layer of insulating film are any one of silicon oxide or silicon nitride.

Furthermore, the first layer of conductive film is any one of chromium, or nickel, or tungsten-containing alloys.

The high electro mobility device is made by adopting the gate-first process according to the present disclosure, wherein gate dielectric sidewalls are utilized to implement the self-alignment of the gate and source; besides, the source and drain of the high electron mobility device can be formed directly by use of the alloying process, the iron implanting process or epitaxy process after formation of the gate since the gate is protected by the passivating layer, featuring a simple technological process while reducing parameter shift of products and enhancing the electrical properties of high electron mobility devices.

### BRIEF DESCRIPTION OF THE SEVERAL VIEWS OF THE DRAWINGS

FIG. 1 is a vertical view of the high electron mobility device based on the gate-first process according to the present disclosure.

FIG. 2 to FIG. 4 are three embodiments of the cross section of the structure as shown in FIG. 1 along Line A-A.

FIG. 5 to FIG. 14 is the process flow diagram of the embodiments of the production method of the high electron mobility device based on the gate-first process according to the present disclosure.

### DETAILED DESCRIPTION OF THE DISCLOSURE

The present disclosure is further detailed by the embodiments in combination with the drawings. For the convenience of description, the thickness of layers and regions is increased or reduced in the figures, so those indicated are not the actual sizes. Despite the fact that these figures cannot reflect the actual size of the device exactly, they completely reflect the mutual relationship in position among regions and constituent structures, especially the upper and lower as well as adjacent relationships among the constituent structures.

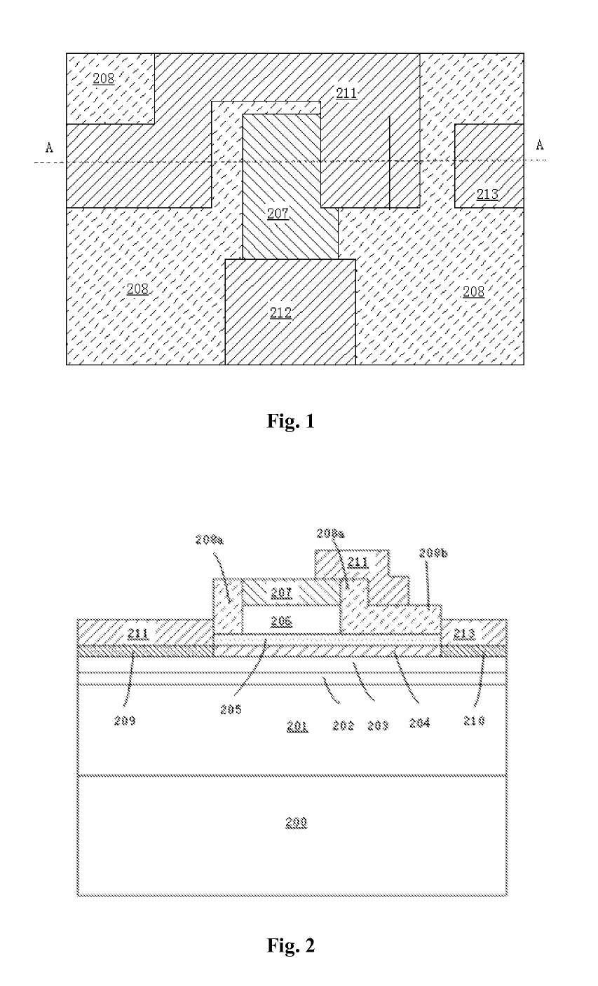

FIG. 1 is a vertical view of the high electron mobility device by use of the gate-first process according to the present disclosure, FIG. 2 to FIG. 4 are three embodiments of the cross section of the structure as shown in FIG. 1 along Line A-A. As shown in FIG. 1 and FIG. 4, the substrate of the high electron mobility device based on the gate-first process according to the present disclosure comprises a base 200 and a GaN buffer layer 201 formed on the base 200; an AlGaN buffer layer 202, a GaN channel layer 203 and an AlGaN isolating layer 204 are formed in turn on the GaN buffer layer 201. A gate dielectric layer 205 is formed on the AlGaN isolating layer 204, a gate 206 and a passivating layer 207 on the gate 206 are formed on the gate dielectric layer 205. A gate dielectric sidewall 208a is formed on either side of the gate 206; a source 209 and a drain 210 are formed on the sides of the gate dielectric layer 205. A dielectric layer 208b is formed between the gate dielectric sidewall 208a close to the drain 210 and the drain 210, the gate dielectric sidewall 208a and the dielectric layer 208b are formed by an insulating material 208, wherein the insulating material 208 can be any one of silicon oxide and silicon nitride. A field plate 211 is covered on the gate dielectric sidewall 208a close to the drain 210, wherein the field plate 211 is connected with the source 209 and extends over the passivating layer 207 and the dielectric layer 208b along the length of the current channel of the device.

As common technology, a contact 212 of the gate and a contact 213 for connecting the gate 206 and the drain 210 to external electrodes on the gate 206 and the drain 210.

In the embodiment of the high electron mobility device based on the gate-first process according to the present disclosure as shown in FIG. 2, the source 209 and the drain 210 are located in the AlGaN isolating layer 204 and formed by the silicon iron doped region in the AlGaN isolating layer 204.

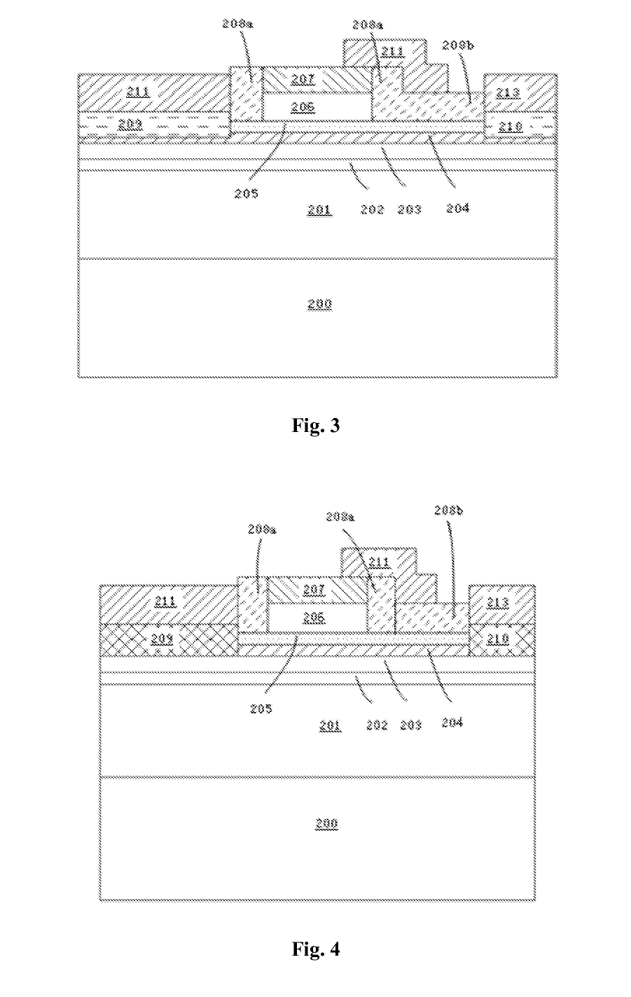

In the embodiment of the high electron mobility device based on the gate-first process according to the present disclosure as shown in FIG. 3, the source 209 and the drain 210 are located on the GaN channel layer 203 and formed by alloy materials.

In the embodiment of the high electron mobility device based on the gate-first process according to the present disclosure as shown in FIG. 4, the source 209 and the drain 210 are located on the GaN channel layer 203 and formed by silion-doped GaN or AlGaN materials.

The following describes the process flow diagram of the embodiments of the production method of the high electron mobility device based on the gate-first process according to the present disclosure.

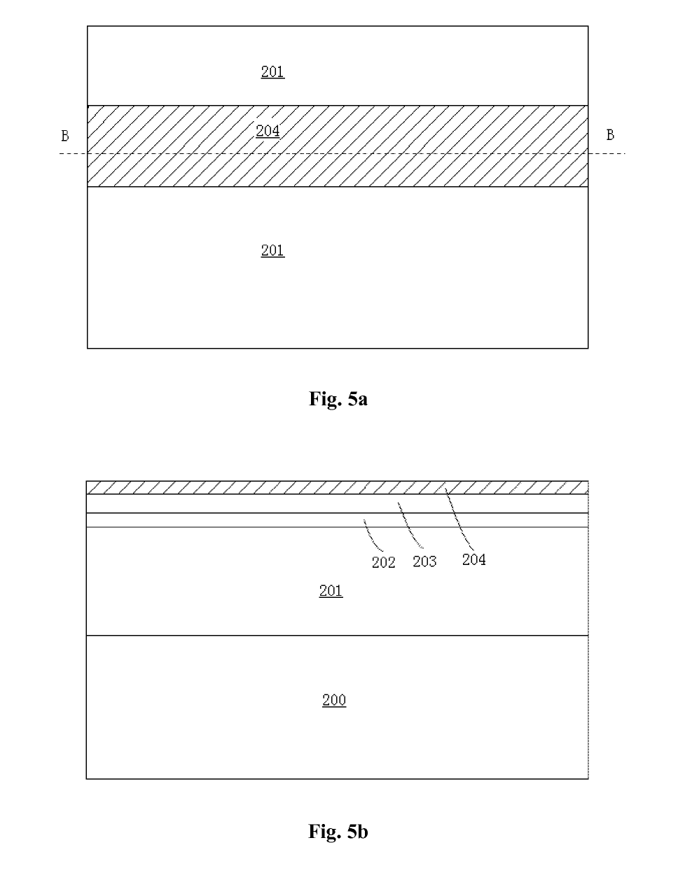

First, as shown in FIG. 5, deposit an about 40 nm thick AlGaN buffer layer 202, an about 40 nm thick GaN channel layer 203 and an about 22 nm thick AlGaN isolating layer 204 in turn on the substrate; deposit a layer of photo-resist on the AlGaN isolating layer 204, and define the location of the active region by masking, exposure and development; and etch way the AlGaN isolating layer 204, the GaN channel layer 203 and the AlGaN buffer layer 202 exposed in turn with a photo-resist as the etching stop layer to form an active region, followed by removal of the resist. Wherein, FIG. 5a is the vertical view of the structure formed and FIG. 5b is the cross-sectional view of the structure as shown in FIG. 5a along Line B-B.

The substrate in the embodiment comprises a base 200 and a GaN buffer layer 201 formed on the base 200, and the base 200 can be silicon, SiC or Al₂O₃.

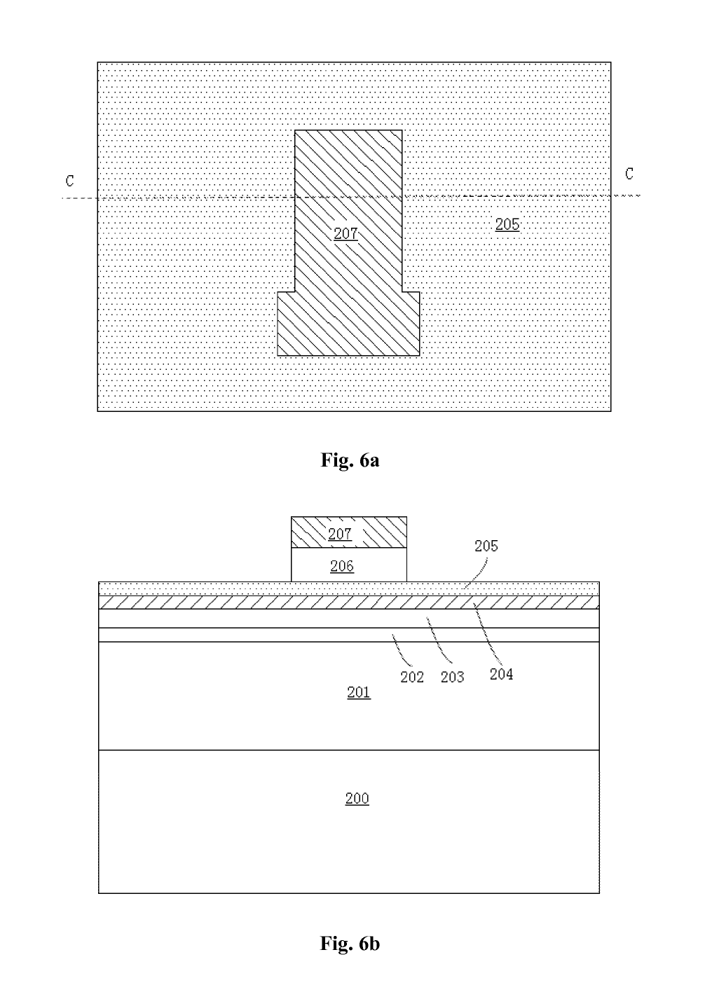

Next, deposit the first layer of insulating film 205, the first layer of conductive film and the second layer of insulating film in turn on the exposed surface of the structure formed; deposit a layer of photo-resist on the second layer of insulating film, and define the location of the device's active region by masking, exposure and development; etch away the second layer of insulating film and the first layer of conductive film exposed in turn with a photo-resist as the etching stop layer, in this way the remaining first layer of conductive film and second layer of insulating film form the gate 206 of the device and the passivating layer 207 on the gate; after removal of the resist, the structure is as shown in FIG. 6, wherein FIG. 6a is the vertical view of the structure formed and FIG. 6b is a cross-sectional view of the structure as shown in FIG. 6a along Line C-C.

The first layer of insulating film 205 can be silicon oxide, silicon nitride, hafnium oxide or Al₂O₃, and the thickness is preferably 8 nm as the gate dielectric layer of the device. The gate 206 can be chromium, or nickel or tungsten-containing alloy, such as nickel-gold alloy, chrome-tungsten alloy, palladium-gold alloy, platinum-gold alloy, nickel-platinum-gold alloy or nickel-palladium-gold alloy. The passivating layer 207 can be any one of silicon oxide or silicon nitride.

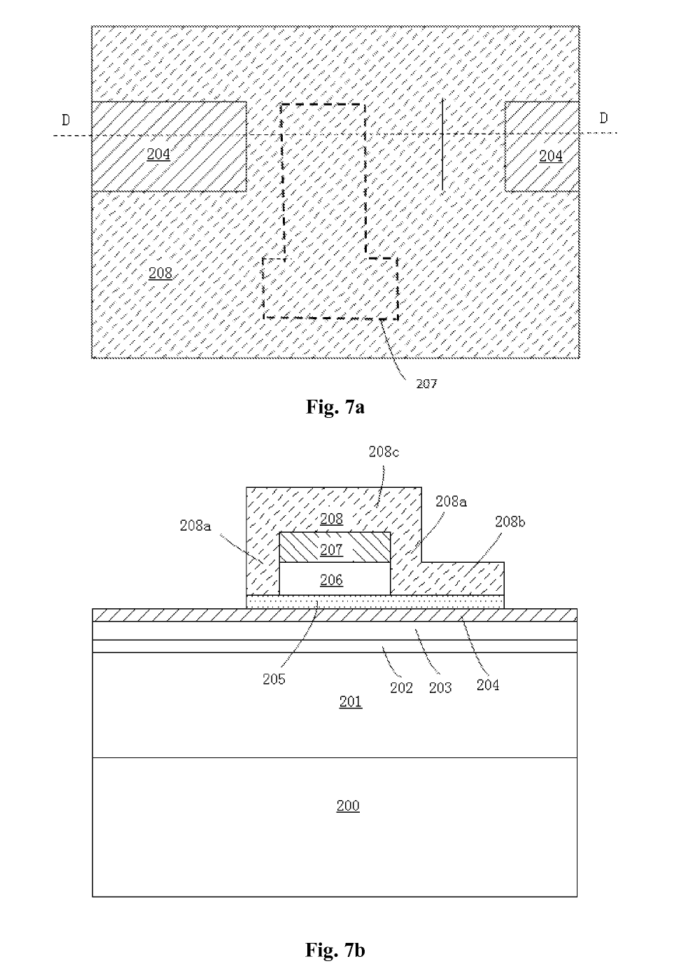

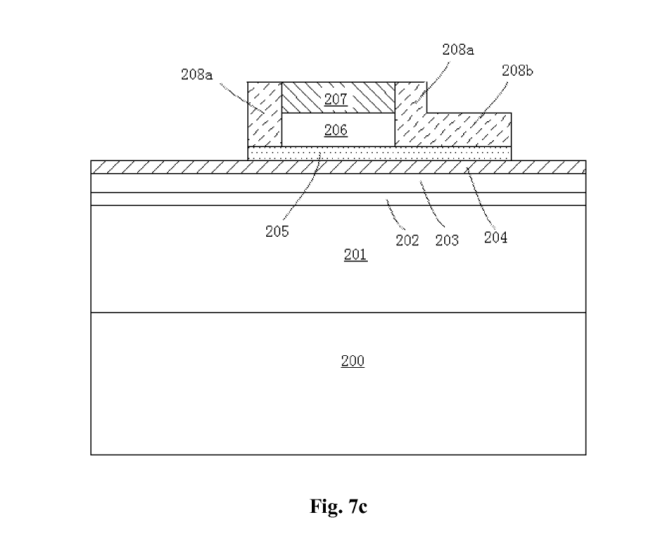

Next, deposit the third layer of insulating film 208 on the exposed surface of the structure formed, deposit a layer of photo-resist on the third layer of the insulating film 208, define the locations of the source and the drain of the device by masking, exposure and development, etch away the third layer of insulating film 208 exposed with a photo-resist as the etching stop layer, and continue to etch away the first layer of insulating film 205 exposed to expose the AlGaN isolating layer 204. In the remaining third layer of insulating film 208, the insulating film 208 located on the sides of the gate 206 can form the gate dielectric sidewalls 208a of the device, the insulating film 208 located between the gate 206 and the defined drain can form the dielectric layer 208b between the gate dielectric sidewall 208a close to the drain and the drain, the insulating film 208c of the insulating film 208 located on the passivating film 207 can serve as part of the passivating layer 207 on the gate 206. After removal of the photo-resist, the structure is as shown in FIG. 7, wherein FIG. 7a is the vertical view of the structure formed and FIG. 7b is the cross-sectional view of the embodiment.

As described above, in etching the third layer of insulating film 208, the insulating film 208c located on the passivating layer 207 and serving as part of the passivating layer 207 located on the gate 206 can also be etched away, as shown in FIG. 7c.

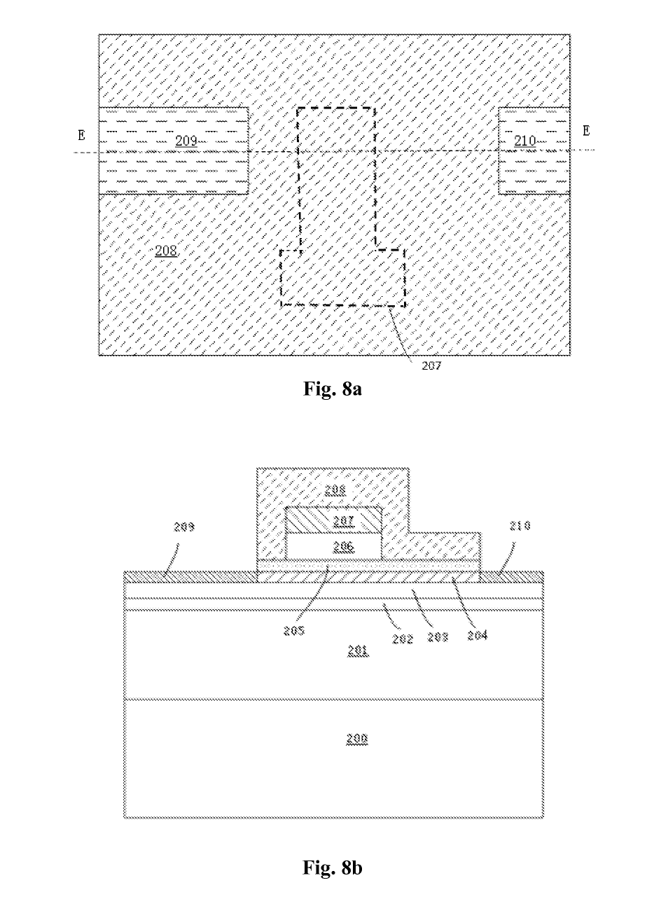

Next, implant silicon ions into the AlGaN isolating layer 204 exposed by the ion implanting process to form a silicon-doped region in the AlGaN isolating layer 204 on the sides of the gate 206, thereby forming the source 209 and the drain 210 of the device, as shown in FIG. 8, wherein FIG. 8a is the vertical view of the structure and the FIG. 8b is a cross-sectional view of the structure as shown in FIG. 8a along Line E-E.

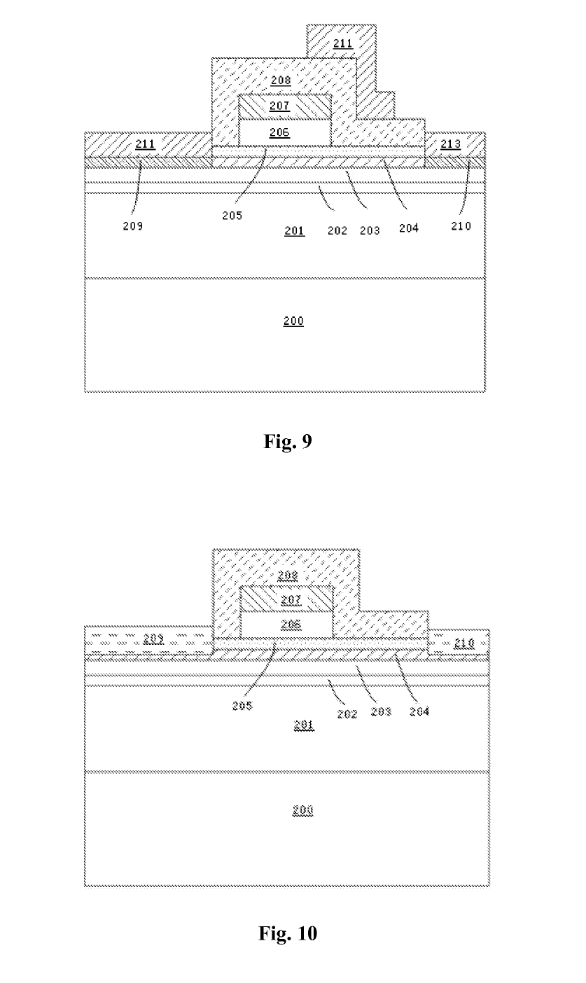

Finally, deposit a new layer of photo-resist on the exposed surface of the structure formed, define the locations of the field plate, gate, source and drain of the device by use of the photo-etching process, and then deposit the second layer of conductive film, wherein the second layer of conductive film can be titanium-aluminium alloy, nickel-aluminium alloy, nickel-platinum alloy or nickel-gold alloy, remove the second layer of conductive film deposited on the photo-resist by use of the lift-off process known in the field and keep the second layer of conductive film not deposited on the photo-resist to form the field plate 211 of the device on the gate dielectric sidewall close to the drain 210, wherein the field plate 211 is connected with the source 209, and form the contact 212 of the gate and the contact 213 of the drain for connecting the gate 206 and the drain 210 to external electrodes, as shown in FIG. 9.

The high electron mobility device based on the gate-first process as shown in FIG. 9 corresponds to the high electron mobility device based on the gate-first process as shown in FIG. 2.

In the production method of the high electron mobility device by use of the gate-first process described in FIG. 5 to FIG. 9, it is workable not to carry out the iron implanting process after etching away the first layer of insulating film 205 exposed; deposit a layer of photo-resist on the exposed surface of the structure formed instead, and define the locations of the source and the drain of the device by masking, exposure and development; form the source 209 and the drain 210 of the device on the AlGaN isolating layer 204 by use of the lift-off process and the alloying process, the process thereof is as below: deposit a layer of conductive film, such as titanium/aluminium/nickel/gold alloy, remove the conductive film deposited on the photo-resist by use of the lift-off process and keep the conductive not deposited on the photo-resist, and form good source-drain contact by high-temperature thermal annealing, as shown in FIG. 10.

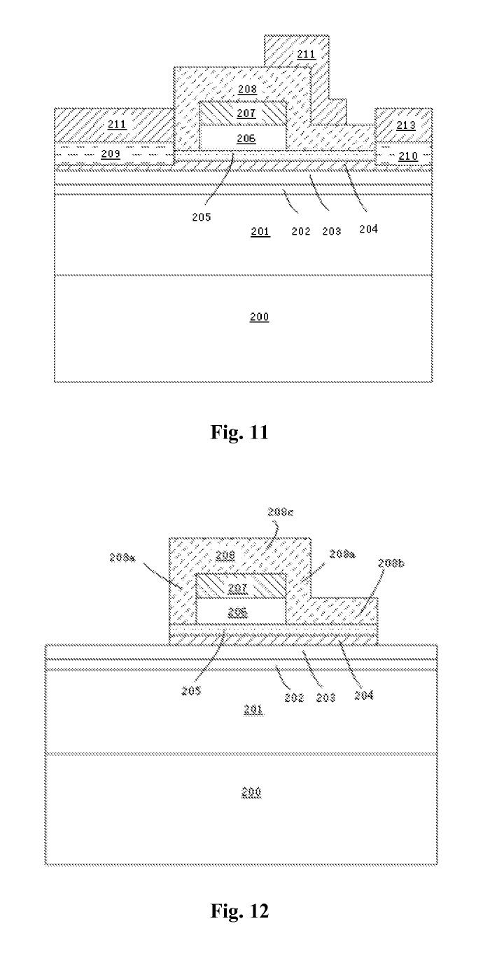

Finally, deposit a new layer of photo-resist on the exposed surface of the structure formed, define the locations of the field plate, gate, source and drain of the device by use of the photo-etching process, and then deposit the second layer of conductive film, wherein the second layer of conductive film can be titanium-aluminium alloy, nickel-aluminium alloy, nickel-platinum alloy or nickel-gold alloy, remove the second layer of conductive film deposited on the photo-resist by use of the lift-off process and keep the second layer of conductive film not deposited on the photo-resist to form the field plate 210 of the device on the gate dielectric sidewall close to the drain 210, wherein the field plate 211 is connected with the source 209, and form the contact 212 of the source and the contact 213 of the drain for connecting the gate 206 and the drain 210 to external electrodes, as shown in FIG. 11.

The high electron mobility device based on the gate-first process as shown in FIG. 11 corresponds to the high electron mobility device based on the gate-first process as shown in FIG. 3.

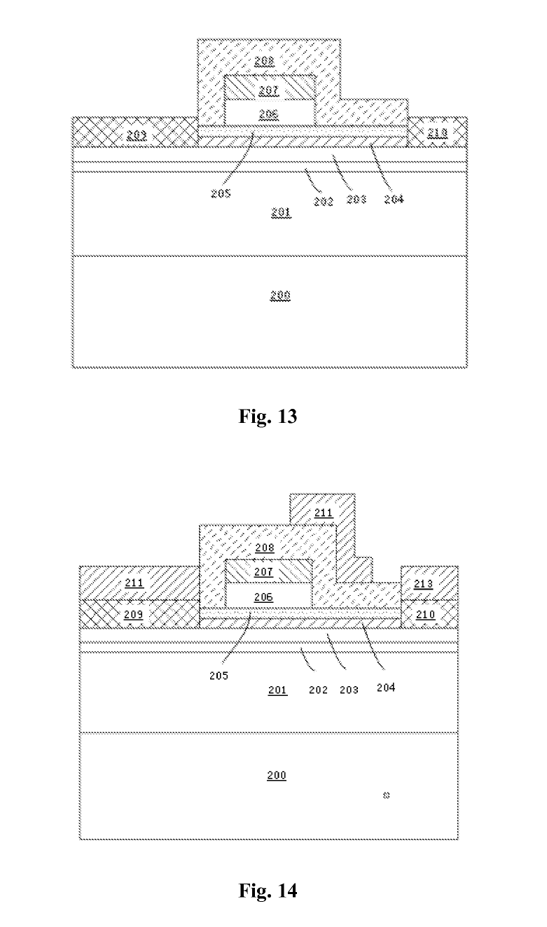

In the production method of the high electron mobility device by use of the gate-first process described above, it is workable to continue to etch away the exposed AlGaN isolating layer 204 after the first layer of insulating film 205 exposed is etched away, as shown in FIG. 12. Next, grow silicon doped GaN or AlGaN by use of the epitaxy process to form the source 209 and the drain 210 of the device on the GaN channel layer 203, and remove the polysilicon GaN, as shown in FIG. 13.

Finally, deposit a new layer of photo-resist on the exposed surface of the structure formed, define the locations of the field plate, gate, source and drain of the device by the photo-etching process, and then deposit the second layer of conductive film, wherein the second layer of conductive film can be titanium-aluminium alloy, nickel-aluminium alloy, nickel-platinum alloy or nickel-gold alloy, remove the second layer of conductive film deposited on the photo-resist by use of the lift-off process known in the field and keep the second layer of conductive film not deposited on the photo-resist to form the field plate 211 of the device on the gate dielectric sidewall close to the drain 210, wherein the field plate 211 is connected with the source 209, and form the contact 212 of the source and the contact 213 of the drain for connecting the gate 206 and the drain 210 to external electrodes, as shown in FIG. 14.

The high electron mobility device based on the gate-first process as shown in FIG. 14 corresponds to the high electron mobility device based on the gate-first process as shown in FIG. 4.

As described above, many other embodiments with great differences can be formed without deviating from the spirit of the present disclosure. It should be understood that the present disclosure is not limited to the specific embodiments described in the specification except those limited by the claims attached.

### INDUSTRIAL APPLICABILITY

The high electro mobility device is made by adopting the gate-first process according to the present disclosure, wherein gate dielectric sidewalls are utilized to implement the self-alignment of the gate and source; besides, the source and drain of the high electron mobility device can be formed directly by use of the alloying process, the iron implanting process or epitaxy process after formation of the gate since the gate is protected by the passivating layer, featuring a simple technological process while reducing parameter shift of products and enhancing the electrical properties of high electron mobility devices.

What is claimed is:

1. A high electron mobility device based on the gate-first process, comprising:
a GaN buffer layer, a GaN channel layer and an isolating layer formed in turn on the substrate;
a gate dielectric layer formed on the AlGaN isolating layer;
wherein it also comprises:
a gate formed on the gate dielectric layer and a passivating layer on the gate;
a gate dielectric sidewall formed on either side of the gate;
a drain and a source formed respectively on the sides of the dielectric layer gate;
a dielectric layer formed between the gate dielectric sidewall close to the drain and the drain to allow the dielectric sidewall close to the drain to extend and make the dielectric sidewalls on the sides of the gate asymmetric in shape;
a field plate covered on the gate dielectric sidewall close to the drain, wherein the field plate is connected with the source and extends over the dielectric layer and the passivating layer on the gate along the length of the current channel of the device.

2. The high electron mobility device based on the gate-first process as presented in claim 1, wherein the isolating layer is AlGaN or indium nitride.

3. The high electron mobility device based on the gate-first process as presented in claim 1, wherein the source and the drain are located on the isolating layer and formed by alloy materials.

4. The high electron mobility device based on the gate-first process as presented in claim 1, wherein the source and the drain are located in the isolating layer and formed by the silicon iron doped region in the isolating layer.

5. The high electron mobility device based on the gate-first process as presented in claim 1, wherein the source and the drain are located on the GaN channel layer and formed by silicon doped GaN or AlGaN materials.

6. The high electron mobility device based on the gate-first process as presented in claim 1, wherein a contact of the gate and a contact of the drain for connecting the gate and the drain to external electrodes on the gate and the drain respectively.

7. A production method of the high electron mobility device based on the gate-first process as presented in claim 1, wherein, comprising:
deposit an AlGaN buffer layer, a GaN channel layer and an isolating layer in turn on the substrate;
etch the isolating layer, the GaN channel layer and the AlGaN buffer layer in turn to form an active region with a photo-resist as the etching stop layer, followed by removal of the resist;
deposit the first layer of insulating film, the first layer of conductive film and the second layer of insulating film in turn on the exposed surface of the structure formed;
define the location of the gate of the device by photo-etching and development;
etch away the second layer of insulating film and the first layer of conductive film exposed in turn with a photo-resist as the etch stop layer, followed by removal of the resist, in this way the remaining first layer of conductive film and second layer of insulating film form the gate and the passivating layer on the gate;
deposit the third layer of insulating film on the exposed surface of the structure formed, define the locations of the source and the drain of the device by masking, exposure and development, etch away the exposed third layer of insulating film with a photo-resist as the etching stop layer, and continue to etch away the first layer of insulating film exposed to expose the isolating layer, followed by removal of the resist, in this way the remaining third layer of insulating film forms the gate dielectric sidewalls on the sides of the gate and the dielectric layer between the gate dielectric sidewall close to the drain and the drain;
form the source and drain of the device;
form a field plate covering the gate dielectric sidewall close to the drain, wherein the field plate is connected with the source and extends over the dielectric layer and the passivating layer on the gate formed along the length of the current channel of the device.

8. The production method of the high electron mobility device based on the gate-first process as presented in claim 7, wherein the isolating layer is AlGaN or indium nitride.

9. The production method of the high electron mobility device based on the gate-first process as presented in claim 7, wherein the formation of the source and the drain of the device includes:
implanting silicon ions into the AlGaN isolating layer exposed to form the source and the drain of the device in the AlGaN isolating layer.

10. The production method of the high electron mobility device based on the gate-first process as presented in claim 7, wherein the formation of the source and the drain of the device includes:
forming the source and the drain of the device on the AlGaN isolating layer exposed by use of the lift-off process and the alloying process.

11. The production method of the high electron mobility device based on the gate-first process as presented in claim 7, wherein the formation of the source and the drain of the device includes:
continuing to etch away the exposed AlGaN isolating layer to expose the GaN channel layer formed; and
growing silicon doped GaN or AlGaN by use of the epitaxy process to form the source and drain of the device on the exposed GaN channel layer.

12. The production method of the high electron mobility device based on the gate-first process as presented in claim 7, wherein the first layer of the insulating film is any one of silicon oxide, silicon nitride, hafnium oxide or Al₂O₃, while the second layer of insulating film and the third layer of insulating film are any one of silicon oxide or silicon nitride.

13. The production method of the high electron mobility device based on the gate-first process as presented in claim 7, wherein the first layer of conductive film is any one of chromium, or nickel, or tungsten-containing alloys.
